(19) United States
(12) Patent Application Publication
(10) Pub. No.: US 2026/0287445 A1
(43) Pub. Date: Sep. 24, 2026

(54) MEMS VARACTOR WITH CONTACT-MODE OPERATION

(71) Applicant: Semtech Corporation, Camarillo, CA (US)

(72) Inventors: Yenhao Chen, Santa Clara, CA (US); Julius Minglin Tsai, San Jose, CA (US)

(21) Appl. No.: 19/565,969

(22) Filed: Mar. 13, 2026

Related U.S. Application Data
(60) Provisional application No. 63/773,761, filed on Mar. 18, 2025.
(60) Provisional application No. 63/854,905, filed on Jul. 31, 2025.

(51) Int. Cl. G01L 1/14; B81B 3/00; B81C 1/00

(52) U.S. Cl. CPC G01L 1/142; B81B 3/0086; B81C 1/00698; B81B 2201/0264; B81B 2203/0127; B81B 2203/04

(57) ABSTRACT

In embodiments of a microelectromechanical system (MEMS) force sensor, the MEMS force sensor includes a flexible member; a first electrode attached to the flexible member, the first electrode being configured to operate at a first voltage; a substrate; a dielectric material; a second electrode attached to the substrate. The second and third electrodes are configured to operate at a second voltage. The dielectric material covers at least one of: (A) the first contact surface; and (B) both the second contact surface and the third contact surface. A measurement device is configured to measure a variable capacitance between the first electrode and the second and third electrodes. The arrangement provides the MEMS force sensor with a concave capacitance-to-force curve. As such, the MEMS force sensor simultaneously achieves greater output dynamic range (large ΔC across a force or pressure span) and high sensitivity at low input forces or pressures.

### RELATED APPLICATIONS

This application claims the benefit of U.S. provisional patent application Ser. No. 63/773,761, filed Mar. 18, 2025, and U.S. provisional patent application Ser. No. 63/854,905, filed Jul. 31, 2025 the disclosures of which are incorporated herein by reference in their entireties.

### FIELD OF THE DISCLOSURE

This disclosure relates generally to microelectromechanical system (MEMS) force sensors and methods of manufacturing the same.

### BACKGROUND

Microelectromechanical system (MEMS) force sensors struggle to simultaneously achieve a higher output dynamic range (large ΔC across a wide force or pressure span) and high sensitivity at low input forces or pressures due to inherent design trade-offs in their mechanical and electrical structures. These sensors often rely on compliant microstructures, such as thin diaphragms or flexures, that deform in response to force, affecting the measured capacitance. Increasing sensitivity at low input levels typically requires making the mechanical structure softer or thinner so it deflects more easily, resulting in a larger capacitance change for small forces. However, this increased compliance limits the maximum force the sensor can handle before it becomes nonlinear, saturates, or even permanently deforms, thus restricting the dynamic range. Conversely, designing the structure to withstand larger forces or to have a broader dynamic range makes it stiffer, which reduces the deflection—and thus the capacitance change—under small loads, lowering sensitivity in the low-force regime. Efforts to enhance one aspect (like low-end sensitivity) often come at the expense of the other (dynamic range), producing a fundamental trade-off in MEMS force sensor design.

### SUMMARY

Embodiment 1. A microelectromechanical system (MEMS) force sensor, includes: a flexible member; a first electrode attached to the flexible member, the first electrode being configured to operate at a first voltage; a substrate; a dielectric material; a second electrode attached to the substrate; the first electrode defining a first contact surface, the second electrode defining a second contact surface; a third electrode defining a third contact surface; the second electrode and the third electrode being configured to operate at a second voltage that is different from the first voltage; the dielectric material covering at least one of: A) the first contact surface; and B) both the second contact surface and the third contact surface; the flexible member being configured such that: if the dielectric material covers the first contact surface, the dielectric material does not contact the second and third contact surfaces in a first position of the flexible member; if the dielectric material covers the first contact surface, the flexible member is configured so that a variable portion of the dielectric material is configured to contact the second contact surface and the third contact surface; if the dielectric material covers both the second contact surface and the third contact surface, the dielectric material does not contact the first contact surface in the first position of the flexible member; if the dielectric material covers both the second contact surface and the third contact surface, the flexible member is configured so that a variable portion of the dielectric material is configured to contact the first contact surface; and a measurement device configured to measure a variable capacitance between the first electrode and the second and third electrodes.

Embodiment 2. The MEMS force sensor of embodiment 1, wherein: the dielectric material covers the first contact surface; the flexible member is configured such that: the dielectric material does not contact the second and third contact surfaces in a first position of the flexible member; and the flexible member is configured so that a variable portion of the dielectric material is configured to contact the second contact surface and the third contact surface.

Embodiment 3. The MEMS force sensor of embodiment 2, wherein there is an airgap between: the dielectric material and the second and third contact surfaces when the flexible member is in the first position.

Embodiment 4. The MEMS force sensor of embodiment 3, wherein a size of the airgap determines a force required so that the variable portion of the dielectric material is configured to contact the second contact surface and the third contact surface.

Embodiment 5. The MEMS force sensor of embodiment 1, wherein: the dielectric material covers both the second contact surface and the third contact surface; the flexible member being configured such that: the dielectric material does not contact the first contact surface in the first position of the flexible member; and the flexible member is configured so that a variable portion of the dielectric material is configured to contact the first contact surface.

Embodiment 6. The MEMS force sensor of embodiment 5, wherein there is an airgap between: the dielectric material and the first contact surface when the flexible member is in the first position.

Embodiment 7. The MEMS force sensor of embodiment 6, wherein a size of the airgap determines a force required so that the variable portion of the dielectric material is configured to contact the first contact surface.

Embodiment 8. The MEMS force sensor of embodiment 1, wherein a capacitance versus force characteristic of the measurement device is a concave curve.

Embodiment 9. The MEMS force sensor of embodiment 1, wherein: the second electrode is shaped as a continuous plate; the third electrode forms a structure that is separated from but surrounds the second electrode.

Embodiment 10.The MEMS force sensor of embodiment 9, wherein the continuous plate includes a circular plate and the third electrode forms a ring around the circular plate.

Embodiment 11. A method of manufacturing a microelectromechanical system (MEMS) force sensor, the method includes: attaching a first electrode to a flexible member, the first electrode being configured to operate at a first voltage; attaching a second electrode to a substrate beneath the flexible member; attaching a third electrode to the substrate, wherein the second electrode and the third electrode are configured to operate at a second voltage that is different from the first voltage and the second and third electrodes are separate from one another; forming a dielectric material covering at least one of:
A) the first contact surface; and B) both the second contact surface and the third contact surface; wherein the flexible member is configured such that: if the dielectric material covers the first contact surface, the dielectric material does not contact the second and third contact surfaces in a first position of the flexible member; if the dielectric material covers the first contact surface, the flexible member is configured so that a variable portion of the dielectric material is configured to contact the second contact surface and the third contact surface; if the dielectric material covers both the second contact surface and the third contact surface, the dielectric material does not contact the first contact surface in the first position of the flexible member; and configuring a measurement device to measure a variable capacitance between the first electrode and the second and third electrodes.

Embodiment 12. A user element includes a microelectromechanical system (MEMS) force sensor, the MEMS force sensor includes: a flexible member; a first electrode attached to the flexible member, the first electrode being configured to operate at a first voltage; a substrate; a dielectric material; a second electrode attached to the substrate; the first electrode defining a first contact surface; the second electrode defining a second contact surface; a third electrode defining a third contact surface; the second electrode and the third electrode being configured to operate at a second voltage that is different from the first voltage; the dielectric material covers at least one of: A) the first contact surface; and B) both the second contact surface and the third contact surface; the flexible member is configured such that: if the dielectric material covers the first contact surface, the dielectric material does not contact the second and third contact surfaces in a first position of the flexible member; if the dielectric material covers the first contact surface, the flexible member is configured so that a variable portion of the dielectric material is configured to contact the second contact surface and the third contact surface; if the dielectric material covers both the second contact surface and the third contact surface, the dielectric material does not contact the first contact surface in the first position of the flexible member; if the dielectric material covers both the second contact surface and the third contact surface, the flexible member is configured so that a variable portion of the dielectric material is configured to contact the first contact surface; and a measurement device configured to measure a variable capacitance between the first electrode and the second and third electrodes.

Embodiment 13. The user element of embodiment 12, wherein: the dielectric material covers the first contact surface; the flexible member is configured such that: the dielectric material does not contact the second and third contact surfaces in a first position of the flexible member; and the flexible member is configured so that a variable portion of the dielectric material is configured to contact the second contact surface and the third contact surface.

Embodiment 14. The MEMS force sensor of embodiment 13, wherein there is an airgap between: the dielectric material and the second and third contact surfaces when the flexible member is in the first position.

Embodiment 15. The MEMS force sensor of embodiment 14, wherein a size of the airgap determines a force required so that the variable portion of the dielectric material is configured to contact the second contact surface and the third contact surface.

Embodiment 16. The MEMS force sensor of embodiment 12, wherein: the dielectric material covers both the second contact surface and the third contact surface; the flexible member is configured such that: the dielectric material does not contact the first contact surface in the first position of the flexible member; and the flexible member is configured so that a variable portion of the dielectric material is configured to contact the first contact surface.

Embodiment 17. The MEMS force sensor of embodiment 16, wherein there is an airgap between: the dielectric material and the first contact surface when the flexible member is in the first position.

Embodiment 18. The MEMS force sensor of embodiment 17, wherein a size of the airgap determines a force required so that the variable portion of the dielectric material is configured to contact the first contact surface

Embodiment 19. The MEMS force sensor of embodiment 12, wherein a capacitance versus force characteristic of the measurement device is a concave curve.

Embodiment 20. The MEMS force sensor of embodiment 12, wherein: the second electrode is shaped as a continuous plate; and the third electrode forms a structure that is separated from but surrounds the second electrode.

In another aspect, any of the foregoing aspects individually or together, and/or various separate aspects and features as described herein, may be combined for additional advantage. Any of the various features and elements as disclosed herein may be combined with one or more other disclosed features and elements unless indicated to the contrary herein.

Those skilled in the art will appreciate the scope of the present disclosure and realize additional aspects thereof after reading the following detailed description of the preferred embodiments in association with the accompanying drawing figures.

### BRIEF DESCRIPTION OF THE DRAWING FIGURES

The accompanying drawing figures incorporated in and forming a part of this specification illustrate several aspects of the disclosure and, together with the description, serve to explain the principles of the disclosure.

FIG. 1A to FIG. 1C illustrate an embodiment of a microelectromechanical system (MEMS) force sensor, in accordance with some embodiments.

FIG. 2 illustrates capacitance versus force curves 202, 204, 206 of the MEMS force sensor 100 shown in FIG. 1A to FIG. 1C, in accordance with some embodiments.

FIG. 3 illustrates another embodiment of a MEMS force sensor, in accordance with some embodiments.

FIG. 4 is flowchart of a method of manufacturing a MEMS force sensor, in accordance with some embodiments.

FIG. 5 is a block diagram of a user element, in accordance with some embodiments.

### DETAILED DESCRIPTION

The embodiments set forth below represent the necessary information to enable those skilled in the art to practice the embodiments and illustrate the best mode of practicing the embodiments. Upon reading the following description in light of the accompanying drawing figures, those skilled in the art will understand the concepts of the disclosure and will recognize applications of these concepts not particularly addressed herein. It should be understood that these concepts and applications fall within the scope of the disclosure and the accompanying claims.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the present disclosure. As used herein, the term “and/or” includes any and all combinations of one or more of the associated listed items.

It will be understood that when an element such as a layer, region, or substrate is referred to as being “on” or extending “onto” another element, it can be directly on or extend directly onto the other element or intervening elements may also be present. In contrast, when an element is referred to as being “directly on” or extending “directly onto” another element, there are no intervening elements present. Likewise, it will be understood that when an element such as a layer, region, or substrate is referred to as being “over” or extending “over” another element, it can be directly over or extend directly over the other element or intervening elements may also be present. In contrast, when an element is referred to as being “directly over” or extending “directly over” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

Relative terms such as “below” or “above” or “upper” or “lower” or “horizontal” or “vertical” may be used herein to describe a relationship of one element, layer, or region to another element, layer, or region as illustrated in the Figures. It will be understood that these terms and those discussed above are intended to encompass different orientations of the device in addition to the orientation depicted in the Figures.

The terminology used herein is for the purpose of describing particular embodiments only and is not intended to be limiting of the disclosure. As used herein, the singular forms “a,” “an,” and “the” are intended to include the plural forms as well, unless the context clearly indicates otherwise. It will be further understood that the terms “comprises,” “comprising,” “includes,” and/or “including” when used herein specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this disclosure belongs. It will be further understood that terms used herein should be interpreted as having a meaning that is consistent with their meaning in the context of this specification and the relevant art and will not be interpreted in an idealized or overly formal sense unless expressly so defined herein.

Embodiments are described herein with reference to schematic illustrations of embodiments of the disclosure. As such, the actual dimensions of the layers and elements can be different, and variations from the shapes of the illustrations as a result, for example, of manufacturing techniques and/or tolerances, are expected. For example, a region illustrated or described as square or rectangular can have rounded or curved features, and regions shown as straight lines may have some irregularity. Thus, the regions illustrated in the figures are schematic and their shapes are not intended to illustrate the precise shape of a region of a device and are not intended to limit the scope of the disclosure. Additionally, sizes of structures or regions may be exaggerated relative to other structures or regions for illustrative purposes and, thus, are provided to illustrate the general structures of the present subject matter and may or may not be drawn to scale. Common elements between figures may be shown herein with common element numbers and may not be subsequently re-described.

Embodiments of a micromechanical system (MEMS) force sensor are disclosed. The MEMS force sensor includes a first electrode attached to a flexible member. The first electrode is disposed over a second electrode and a third electrode attached to a substrate. The first electrode is configured to operate at a first voltage, while the second and third electrodes, while physically separate from one another, both operate at a second voltage that is different from the first voltage. A dielectric material is provided to cover either the first electrode surface of the first electrode or both the second electrode surface of the second electrode and the third electrode surface of the third electrode. The capacitance of the MEMS force sensor varies as the airgap between the first electrode and the second and third electrodes is closed and as a zipper action has greater portions of the dielectric material making contact with corresponding electrodes. The arrangement provides the MEMS force sensor with a concave capacitance-to-force curve. The described embodiments of the MEMS force sensor simultaneously achieve a higher output dynamic range (large ΔC across a wide force or pressure span) and high sensitivity at low input forces or pressures.

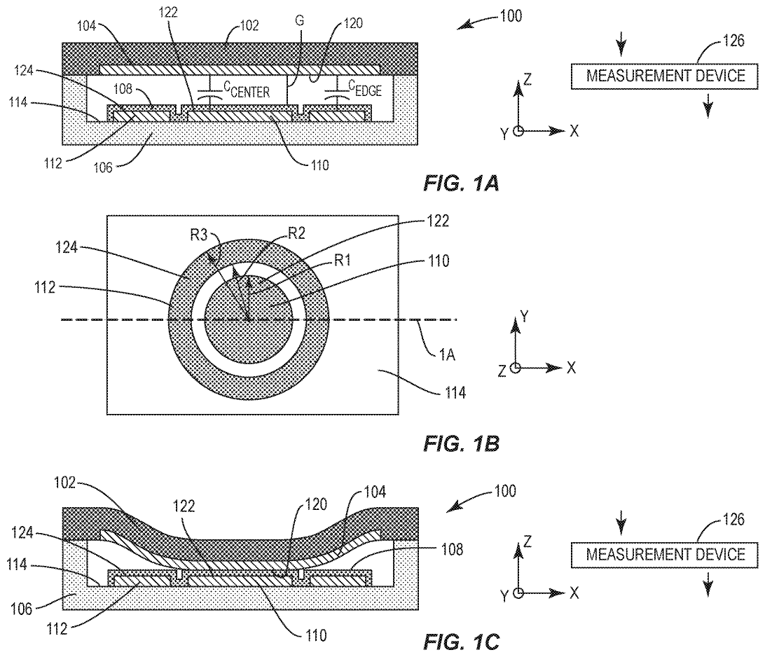

FIG. 1A to FIG. 1C illustrate an embodiment of a MEMS force sensor 100, in accordance with some embodiments.

The MEMS force sensor 100 includes a flexible member 102, a first electrode 104 attached to the flexible member 102, a substrate 106, a dielectric material 108, a second electrode 110 attached to the substrate 106, and a third electrode 112 attached to the substrate 106. FIG. 1A illustrates a cross-sectional view of the MEMS force sensor 100. In this embodiment, the substrate 106 defines a top surface 114, where the second electrode 110 and the third electrode 112 are attached to the top surface 114 of the substrate 106. FIG. 1B illustrates a top view of the second electrode 110 and the third electrode 112 on the top surface 114, along with a cross-sectional line 1A illustrating where the cross section for FIG. 1A is taken. FIG. 1C illustrates the flexible member 102 depressed downward in an engagement position as opposed to FIG. 1A, which shows the MEMS force sensor 100 in a non-engaged position.

The first electrode 104 is configured to operate at a first voltage, which is generally a first direct current (DC) voltage. The second electrode 110 and the third electrode 112 are both configured to operate at a second voltage (e.g., second DC voltage) that is different from the first voltage. Since the second electrode 110 and the third electrode 112 both operate at the second voltage, the second electrode 110 and the third electrode 112 do not operate at independent voltages.

Horizontal directions may be defined relative to an X-axis, which defines a first horizontal direction on the top surface 114 of the substrate, and a Y-axis, which defines a second horizontal direction on the top surface 114. The X-axis and the Y-axis are orthogonal, and thus the first horizontal direction (parallel to the X-axis) and the second horizontal direction (parallel to the Y-axis) are also orthogonal. Both the X-axis and the Y-axis are defined within the plane that makes up the top surface 114. A Z-axis defines a vertical direction and is orthogonal to both the X-axis and the Y-axis.

A variable capacitor having a variable capacitance is formed by the first electrode 104 in the flexible member 102 and the second electrode 110 and the third electrode 112 on the top surface 114 of the substrate 106. As shown by FIG. 1A and FIG. 1C, the flexible member 102 goes from a non-engaged position (i.e., as shown in FIG. 1A) toward the second electrode 110 and the third electrode 112. The flexible member 102 is depressed downward by a force on the flexible member 102. The first electrode 104 has a first contact surface 120, the second electrode 110 has a second contact surface 122, and the third electrode 112 has a third contact surface 124. In this embodiment, the dielectric material 108 completely covers that second contact surface 122 of the second electrode 110 and the third contact surface 124 of the third electrode 112. As shown in FIG. 1A, in the non-engaged position, the first contact surface 120 does not contact the dielectric material 108 on the second contact surface 122 and the third contact surface 124. In other words, the dielectric material 108 does not contact the first contact surface 120 in the non-engaged position of the flexible member 102. However, as the flexible member is depressed and flexed downward, the flexible member 102 is configured so that a variable portion of the dielectric material 108 on the second contact surface 122 and the third contact surface 124 is configured to contact the first contact surface 120 of the first electrode 104. Thus, the variable capacitance of the MEMS force sensor 100 changes as the portion of the dielectric material 108 on the second contact surface 122 and the third contact surface 124 that contacts the first contact surface 120 changes. Since the portion of the dielectric material 108 on the second contact surface 122 and the third contact surface 124 that contacts the first contact surface 120 varies based on the downward force applied to the flexible member 102, the variable capacitance of the MEMS force sensor 100 is related to the force applied to the flexible member 102. The dielectric material 108 may be formed from a silicon dioxide or other suitable material.

The MEMS force sensor 100 further includes a measurement device 126 that is configured to measure the variable capacitance between the first electrode 104 and the second electrode 110 and third electrode 112. The measurement device 126 typically includes a capacitance measurement circuit capable of detecting very small changes in capacitance, often in the femtofarad (fF) to picofarad (pF) range, which are characteristic of some embodiments of the MEMS force sensor 100. Several circuit architectures can be employed for this purpose, such as oscillator-based circuits that relate capacitance changes to frequency shifts, charge-discharge timing circuits that determine capacitance by measuring how long it takes to charge the capacitor to a set voltage, capacitance-to-voltage converters, or alternating current (AC) bridge circuits that detect differential changes compared with a reference capacitor.

In this embodiment, the first electrode 104 is integrated into the flexible member 102 so that the first contact surface 120 of the first electrode 104 forms a portion of the bottom surface of the flexible member 102 that is above the second contact surface 122 of the second electrode 110 and a third contact surface 124 of the third electrode 112. There is a airgap G between the first contact surface 120 of the first electrode 104 and the second and third contact surfaces 122, 124 of the second and third electrodes 110, 112. When no force (i.e., a force with a magnitude equal to zero) is applied on the flexible member 102, as shown in FIG. 1A, the flexible member 102 is in the non-engaged position and the gap G relative to the Z-axis has the greatest amount of displacement between the first contact surface 120 of the first electrode 104 and the second and third contact surfaces 122, 124. However, as a force F is increased on the flexible member 102, the airgap G decreases along the length of the first contact surface 120 until increasing portions of the first contact surface 120 make contact with, first, the second contact surface 122 and, then eventually, increasing portions of the third contact surface 124. In this manner, the variable capacitance of the MEMS force sensor 100 varies as the amount of force in a downward direction varies on the flexible member 102. Thus, a size of the airgap G determines a force required so that the variable portion of the dielectric material 108 is configured to contact the second contact surface 122 and the third contact surface 124.

As shown in FIG. 1B, the second electrode 110 is shaped as a continuous plate. In this embodiment, the second electrode is specifically shaped as a circular plate, although in other embodiments other shapes may be used. The third electrode 112 forms a structure that is separated from but surrounds the second electrode 110. In this specific embodiment, the third electrode 112 forms a circular ring around the second electrode 110. Other shapes may be used for the third electrode 112 to surround the second electrode 110. In this particular configuration, electrode material is provided from an origin (which is a geometric center of the second electrode 110) to a radius R1 to form the second electrode 110. From the radius R1 to a radius R2, no electrode material is provided and thus this forms a horizontal gap between the second electrode 110 and the third electrode 112. From the radius R2 to a radius R3, electrode material is provided to form the third electrode 112.

In some embodiments, the electrode material that may be used for the first electrode 104, the second electrode 110, and the third electrode 112 may include aluminum, copper, nickel, silver, gold, platinum, or any other suitable conductive material. The flexible member 102 may be made from silicon, polysilicon, silicon dioxide (SiO₂), silicon nitride (Si₃N₄), polyimide, polydimethylsiloxane (PDMS), and/or any other suitable material. The substrate 106 may be formed from a piezoelectric material such as lead zirconate titanate (PZT), zinc oxide (ZnO), and quartz. The measurement device 126 is configured to detect the electric signal generated by the substrate 106 in order to measure the capacitance and thereby determine the force applied to the flexible member 102.

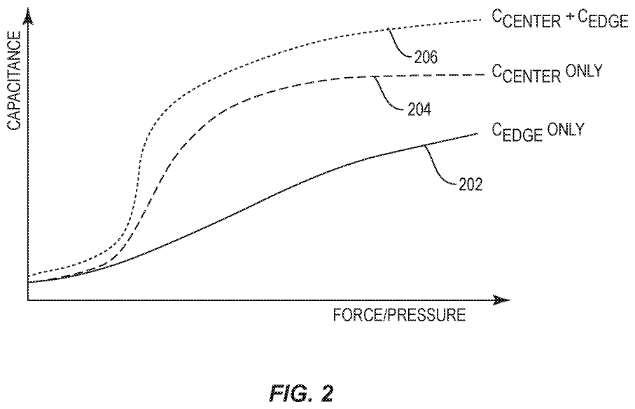

FIG. 2 illustrates capacitance versus force curves 202, 204, 206 of the MEMS force sensor 100 shown in FIG. 1A to FIG. 1C, in accordance with some embodiments.

Capacitance versus force curve 202 is the capacitance versus force curve if the first contact surface 120 is only allowed to contact dielectric material 108 covering the third contact surface 124 of the third electrode 112 but not the dielectric material 108 on the second contact surface 122 of the second electrode 110. As shown, the capacitance versus force curve 202 is substantially linear. Capacitance versus force curve 204 is the capacitance versus force curve if the first contact surface 120 is only allowed to contact dielectric material 108 covering the second contact surface 122 of the second electrode 110 but not the dielectric material 108 on the third contact surface 124 of the third electrode 112. As shown, the capacitance versus force curve 204 is concave. While the airgap remains, the bottom portion of the capacitance versus force curve 204 remains substantially flat. Then, the capacitance versus force curve 204 increases linearly rapidly as more and more of the first contact surface 120 makes contact with the dielectric material over the second contact surface 122. After the first contact surface 120 fully engages the dielectric material over the second contact surface 122, the capacitance versus force curve 204 again remains relatively flat.

Capacitance versus force curve 206 is the capacitance versus force curve if the first contact surface 120 is allowed to contact dielectric material 108 covering the second contact surface 122 of the second electrode 110 and the dielectric material 108 on the third contact surface 124 of the third electrode 112. The capacitance versus force curve 206 is thus a combination of the capacitance versus force curve 204 and the capacitance versus force curve 202. Thus, as shown, the capacitance versus force curve 206 is concave. While the airgap remains, the bottom portion of the capacitance versus force curve 206 remains somewhat flat but with a bit of linearity due to the effects of the capacitance versus force curve 202. Then, the capacitance versus force curve 206 increases linearly rapidly as more and more of the first contact surface 120 makes contact with the dielectric material over the second contact surface 122. After the first contact surface 120 fully engages the dielectric material over the second contact surface 122, the capacitance versus force curve 206 again remains somewhat flat but with some linearity due to the effects of the capacitance versus force curve 202.

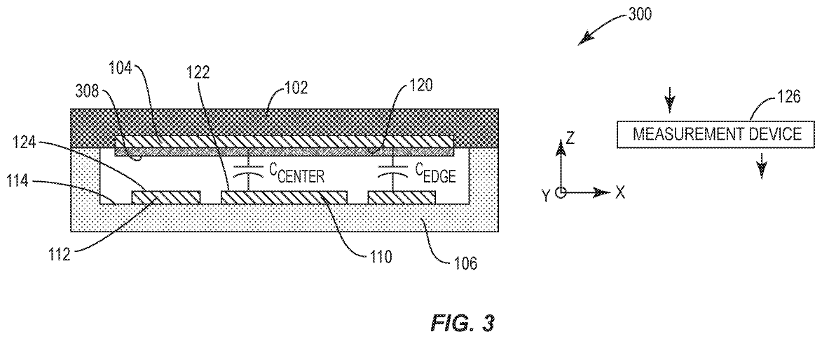

FIG. 3 illustrates another embodiment of a MEMS force sensor 300, in accordance with some embodiments.

The MEMS force sensor 300 is the same as the MEMS force sensor 100 shown in FIG. 1A to FIG. 1C except that the MEMS force sensor 300 does not include the dielectric layer 108 that covers the second contact surface 122 and third contact surface 124. Instead, the MEMS force sensor 300 includes a dielectric layer 308 that covers the first contact surface 120 of the first electrode 104.

As shown in FIG. 3, the second contact surface 122 and the third contact surface 124 do not contact the dielectric material 308 on the first contact surface 120 in the non-engaged position. In other words, the dielectric material 308 does not contact the second contact surface 122 and the third contact surface 124 when the flexible member 102 is in the non-engaged position. However, as the flexible member is depressed and flexed downward, the flexible member 102 is configured so that a variable portion of the dielectric material 308 on the first contact surface 120 is configured to contact the second contact surface 122 and the third contact surface 124. Thus, the variable capacitance of the MEMS force sensor 300 changes as the portion of the dielectric material 308 on the first contact surface 120 contacting the second contact surface 122 and the third contact surface 124 changes. Since the portion of the dielectric material 308 on the first contact surface 120 that contacts the second contact surface 122 and the third contact surface 124 varies based on the downward force applied to the flexible member 102, the variable capacitance of the MEMS force sensor 300 is related to the force applied to the flexible member 102.

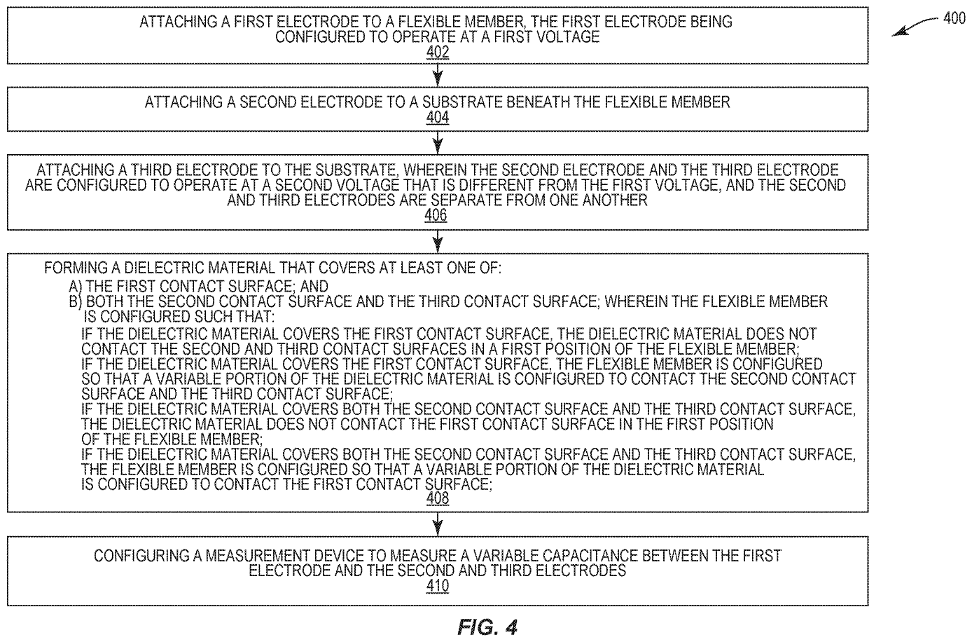

FIG. 4 is flowchart 400 of a method of manufacturing a MEMS force sensor, in accordance with some embodiments.

The flowchart 400 may be used to manufacture the MEMS force sensor 100 in FIG. 1 or the MEMS force sensor 300 in FIG. 3, in accordance with some embodiments. Flowchart 400 includes blocks 402-410. Flow begins at block 402.

At block 402, a first electrode is attached to a flexible member, and the first electrode is configured to operate at a first voltage. An example of the first electrode is the first electrode 104 in FIG. 1A to FIG. 1C and FIG. 3. An example of the flexible member is the flexible member 102 in FIG. 1A, FIG. 1C, and FIG. 3. Flow then proceeds to block 404.

At block 404, a second electrode is attached to a substrate beneath the flexible member. An example of the second electrode is the second electrode 110 shown in FIG. 1A to FIG. 1C and FIG. 3. An example of the substrate is the substrate 106 shown in FIG. 1A, FIG. 1C, and FIG. 3. Flow then proceeds to block 406.

At block 406, a third electrode is attached to the substrate, wherein the second electrode and the third electrode are configured to operate at a second voltage that is different from the first voltage, and the second and third electrodes are separate from one another. An example of the third electrode is the third electrode 112 shown in FIG. 1A to FIG. 1C and FIG. 3. Flow then proceeds to block 408.

At block 408, a dielectric material is formed. An example of the dielectric material is the dielectric material 108 in FIG. 1A and FIG. 1C and the dielectric material 308 in FIG. 3. The dielectric material covers at least one of (A) the first contact surface (such as the dielectric material 108 in FIG. 1A and FIG. 1C) and (B) both the second contact surface and the third contact surface (such as the dielectric material 308 in FIG. 3). An example of the first electrode surface is the first contact surface 120 shown in FIG. 1A, FIG. 1C, and FIG. 3. An example of the second electrode surface is the second contact surface 122 shown in FIG. 1A, FIG. 1C, and FIG. 3. An example of the third electrode surface is the third contact surface 124 shown in FIG. 1A, FIG. 1C, and FIG. 3. If the dielectric material covers the first contact surface, the dielectric material does not contact the second and third contact surfaces in a first position of the flexible member, as with the dielectric material 308 in FIG. 3. If the dielectric covers the first contact surface, the flexible member is configured so that a variable portion of the dielectric material is configured to contact the second contact surface and the third contact surface, as with the dielectric material 308 in FIG. 3. If the dielectric material covers both the second contact surface and the third contact surface, the dielectric material does not contact the first contact surface in the first position of the flexible member, such as the dielectric material 108 in FIG. 1A and FIG. 1C. If the dielectric material covers both the second contact surface and the third contact surface, the flexible member is configured so that a variable portion of the dielectric material is configured to contact the first contact surface, such as the dielectric material 108 in FIG. 1A and FIG. 1C. Flow then proceeds to block 410.

At block 410, a measurement device is configured to measure a variable capacitance between the first electrode and the second and third electrodes, such as the measurement device 126 in FIG. 1A, FIG. 1C, and FIG. 3.

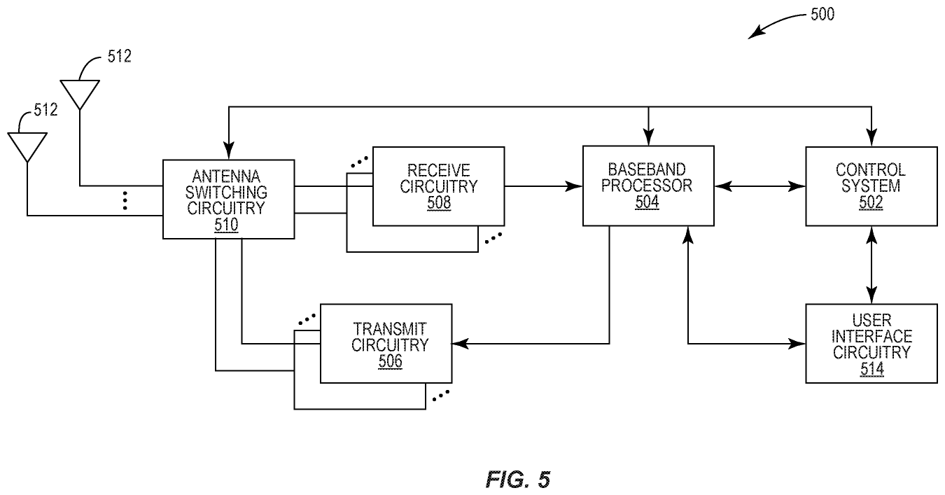

FIG. 5 is a block diagram of a user element 500, in accordance with some embodiments.

With reference to FIG. 5, the concepts described above may be implemented in various types of user elements 500, such as mobile terminals, smart watches, tablets, computers, navigation devices, access points, and like wireless communication devices that support wireless communications, such as cellular, wireless local area network (WLAN), Bluetooth, and near-field communications. The user element 500 will generally include a control system 502, a baseband processor 504, transmit circuitry 506, receive circuitry 508, antenna switching circuitry 510, multiple antennas 512, and user interface circuitry 514. In a non-limiting example, the control system 502 may be a field-programmable gate array (FPGA) or an application-specific integrated circuit (ASIC). In this regard, the control system 502 may include at least a microprocessor, an embedded memory circuit, and a communication bus interface. The receive circuitry 508 receives radio frequency signals via the antennas 512 and through the antenna switching circuitry 510 from one or more base stations. A low-noise amplifier and a filter cooperate to amplify and remove broadband interference from the received signal for processing. Downconversion and digitization circuitry (not shown) will then downconvert the filtered, received signal to an intermediate or baseband frequency signal, which is then digitized into one or more digital streams using analog-to-digital converters (ADCs).

The baseband processor 504 processes the digitized received signal to extract the information or data bits conveyed in the received signal. This processing typically comprises demodulation, decoding, and error correction operations, as will be discussed in greater detail below. The baseband processor 504 is generally implemented in one or more digital signal processors (DSPs) and application-specific integrated circuits (ASICs).

For transmission, the baseband processor 504 receives digitized data, which may represent voice, data, or control information, from the control system 502, which it encodes for transmission. The encoded data is output to the transmit circuitry 506, where a digital-to-analog converter (DAC) converts the digitally encoded data into an analog signal and a modulator modulates the analog signal onto a carrier signal that is at a desired transmit frequency or frequencies. A power amplifier will amplify the modulated carrier signal to a level appropriate for transmission and deliver the modulated carrier signal to the antennas 512 through the antenna switching circuitry 510. The multiple antennas 512 and the replicated transmit circuitry 506 and receive circuitry 508 may provide spatial diversity. Modulation and processing details will be understood by those skilled in the art.

It is contemplated that any of the foregoing aspects, and/or various separate aspects and features as described herein, may be combined for additional advantage. Any of the various embodiments as disclosed herein may be combined with one or more other disclosed embodiments unless indicated to the contrary herein.

Those skilled in the art will recognize improvements and modifications to the preferred embodiments of the present disclosure. All such improvements and modifications are considered within the scope of the concepts disclosed herein and the claims that follow.

What is claimed is:

1. A microelectromechanical system (MEMS) force sensor, comprising:
a flexible member;
a first electrode attached to the flexible member, the first electrode being configured to operate at a first voltage;
a substrate;
a dielectric material;
a second electrode attached to the substrate;
the first electrode defining a first contact surface;
the second electrode defining a second contact surface;
a third electrode defining a third contact surface;
the second electrode and the third electrode being configured to operate at a second voltage that is different from the first voltage;
the dielectric material covering at least one of:
the first contact surface; and
both the second contact surface and the third contact surface;
the flexible member being configured such that:
if the dielectric material covers the first contact surface, the dielectric material does not contact the second and third contact surfaces in a first position of the flexible member;
if the dielectric material covers the first contact surface, the flexible member is configured so that a variable portion of the dielectric material is configured to contact the second contact surface and the third contact surface;
if the dielectric material covers both the second contact surface and the third contact surface, the dielectric material does not contact the first contact surface in the first position of the flexible member;
if the dielectric material covers both the second contact surface and the third contact surface, the flexible member is configured so that a variable portion of the dielectric material is configured to contact the first contact surface; and
a measurement device configured to measure a variable capacitance between the first electrode and the second and third electrodes.

2. The MEMS force sensor of claim 1, wherein:
the dielectric material covers the first contact surface;
the flexible member is configured such that:
the dielectric material does not contact the second and third contact surfaces in a first position of the flexible member; and
the flexible member is configured so that a variable portion of the dielectric material is configured to contact the second contact surface and the third contact surface.

3. The MEMS force sensor of claim 2, wherein there is an airgap between:
the dielectric material and the second and third contact surfaces when the flexible member is in the first position.

4. The MEMS force sensor of claim 3, wherein a size of the airgap determines a force required so that the variable portion of the dielectric material is configured to contact the second contact surface and the third contact surface.

5. The MEMS force sensor of claim 1, wherein:
the dielectric material covers both the second contact surface and the third contact surface;
the flexible member being configured such that:
the dielectric material does not contact the first contact surface in the first position of the flexible member; and
the flexible member is configured so that a variable portion of the dielectric material is configured to contact the first contact surface.

6. The MEMS force sensor of claim 5, wherein there is an airgap between:
the dielectric material and the first contact surface when the flexible member is in the first position.

7. The MEMS force sensor of claim 6, wherein a size of the airgap determines a force required so that the variable portion of the dielectric material is configured to contact the first contact surface.

8. The MEMS force sensor of claim 1, wherein a capacitance versus force characteristic of the measurement device is a concave curve.

9. The MEMS force sensor of claim 1, wherein:
the second electrode is shaped as a continuous plate;
the third electrode forms a structure that is separated from but surrounds the second electrode.

10. The MEMS force sensor of claim 9, wherein the continuous plate comprises a circular plate and the third electrode forms a ring around the circular plate.

11. A method of manufacturing a microelectromechanical system (MEMS) force sensor, the method comprising:
attaching a first electrode to a flexible member, the first electrode being configured to operate at a first voltage;
attaching a second electrode to a substrate beneath the flexible member;
attaching a third electrode to the substrate, wherein the second electrode and the third electrode are configured to operate at a second voltage that is different from the first voltage and the second and third electrodes are separate from one another;
forming a dielectric material covering at least one of:
the first contact surface; and
both the second contact surface and the third contact surface;
wherein the flexible member is configured such that:
if the dielectric material covers the first contact surface, the dielectric material does not contact the second and third contact surfaces in a first position of the flexible member;
if the dielectric material covers the first contact surface, the flexible member is configured so that a variable portion of the dielectric material is configured to contact the second contact surface and the third contact surface;
if the dielectric material covers both the second contact surface and the third contact surface, the dielectric material does not contact the first contact surface in the first position of the flexible member; and
configuring a measurement device to measure a variable capacitance between the first electrode and the second and third electrodes.

12. A user element comprising a microelectromechanical system (MEMS) force sensor, the MEMS force sensor comprising:
a flexible member;
a first electrode attached to the flexible member, the first electrode being configured to operate at a first voltage;
a substrate;
a dielectric material;
a second electrode attached to the substrate;
the first electrode defining a first contact surface;
the second electrode defining a second contact surface;
a third electrode defining a third contact surface;
the second electrode and the third electrode being configured to operate at a second voltage that is different from the first voltage;
the dielectric material covers at least one of:
the first contact surface; and
both the second contact surface and the third contact surface;
the flexible member is configured such that:
if the dielectric material covers the first contact surface, the dielectric material does not contact the second and third contact surfaces in a first position of the flexible member;
if the dielectric material covers the first contact surface, the flexible member is configured so that a variable portion of the dielectric material is configured to contact the second contact surface and the third contact surface;
if the dielectric material covers both the second contact surface and the third contact surface, the dielectric material does not contact the first contact surface in the first position of the flexible member;
if the dielectric material covers both the second contact surface and the third contact surface, the flexible member is configured so that a variable portion of the dielectric material is configured to contact the first contact surface; and
a measurement device configured to measure a variable capacitance between the first electrode and the second and third electrodes.

13. The user element of claim 12, wherein:
the dielectric material covers the first contact surface;
the flexible member is configured such that:
the dielectric material does not contact the second and third contact surfaces in a first position of the flexible member; and
the flexible member is configured so that a variable portion of the dielectric material is configured to contact the second contact surface and the third contact surface.

14. The user element of claim 13, wherein there is an airgap between:
the dielectric material and the second and third contact surfaces when the flexible member is in the first position.

15. The user element of claim 14, wherein a size of the airgap determines a force required so that the variable portion of the dielectric material is configured to contact the second contact surface and the third contact surface.

16. The user element of claim 12, wherein:
the dielectric material covers both the second contact surface and the third contact surface;
the flexible member is configured such that:
the dielectric material does not contact the first contact surface in the first position of the flexible member; and
the flexible member is configured so that a variable portion of the dielectric material is configured to contact the first contact surface.

17. The user element of claim 16, wherein there is an airgap between:
the dielectric material and the first contact surface when the flexible member is in the first position.

18. The user element of claim 17, wherein a size of the airgap determines a force required so that the variable portion of the dielectric material is configured to contact the first contact surface.

19. The user element of claim 12, wherein a capacitance versus force characteristic of the measurement device is a concave curve.

20. The user element of claim 12, wherein:
the second electrode is shaped as a continuous plate; and
the third electrode forms a structure that is separated from but surrounds the second electrode.
